(19) United States
(12) Patent Application Publication
(10) Pub. No.: US 2025/0029820 A1
(43) Pub. Date: Jan. 23, 2025

(54) ACTIVELY COOLED ANODE FOR SPUTTERING PROCESSES

(71) Applicant: INTEVAC, INC., Santa Clara, CA (US)

(72) Inventor: Patrick Morse, Tucson, AZ (US)

(21) Appl. No.: 18/774,819

(22) Filed: Jul. 16, 2024

Related U.S. Application Data
(60) Provisional application No. 63/527,561, filed on Jul. 18, 2023.

(51) Int. Cl. H01J 37/34; C23C 14/34; C23C 14/35

(52) U.S. Cl. CPC H01J 37/3438; C23C 14/3407; C23C 14/352; H01J 37/3405; H01J 37/3423; H01J 37/3441; H01J 2237/002; H01J 2237/332

(57) ABSTRACT

A sputtering chamber has a rotating cylindrical sputtering target inside a vacuum enclosure. An anode is positioned next to the target, having an outer copper pipe, a magnetic core axially located within the copper pipe, and liquid cooling channels formed between the magnetic core and the outer copper pipe. A shield is positioned to block line-of-sight from the plasma to the anode, the shield shaped as a half pipe exposing surface of the copper pipe in a direction away from the plasma.

### RELATED APPLICATIONS

This Application claims priority benefit from U.S. Provisional Application, Ser. No. 63/527,561, filed Jul. 18, 2023, the disclosure of which is incorporated herein by reference in its entirety.

### BACKGROUND

### 1. Field

This disclosure relates to anodes for sputtering chambers and to sputtering arrangements and chambers using such anodes.

### 2. Related Art

Various designs for sputtering chambers, cathodes and anodes have been previously disclosed by the subject assignee. See, e.g., U.S. Pat. No. 11,456,162, U.S. Publications 2024/0191341, and Application PCT/US23/83445, which are incorporated herein in their entirety by reference. While not necessary for complete understanding of this disclosure, the reader is nevertheless encouraged to review these disclosures. Notably, while this disclosure is suitable for implementation within the apparatus disclosed in the referenced publications, it may also be beneficially implemented in other apparatus designs.

As disclosed in the cited publications, plasma physical vapor deposition (PVD) or magnetically confined sputtering processes ionize process gases to thereby ignite and maintain plasma in a vacuum chamber. Positively charged ionized gas atoms produced by the plasma are accelerated towards a negatively charged target's surface, which is made of a material to be deposited as a desired thin film on a substrate. Permanent magnets are located under the target surface and are used to produce static magnetic fields that magnetically confine electrons released from the ionization process and the confinement of electron are utilized to produce more plasma near the target's cathode within the magnetic fields. An anode is positioned near the cathode within the vacuum chamber to complete the electrical circuit.

Anodes utilized in magnetically confined sputtering processes need to be able to receive electrons leaving the magnetic confinement and return them to the power supply to complete the electrical circuit. In order to return the electrons to the power supply the electrons need to be able to enter the anode surface, travel along the anode to a feedthrough in the vacuum chamber, and then travel out of the chamber through the feedthrough and to the power supply. In low power sputtering applications this is not a difficult challenge, but in higher power sputtering applications that run at relatively low voltages this can become very difficult. The difficulty arises in the fact that the current in the anode can create magnetic fields that repel the electrons and the electrons traveling through a vacuum space repel each other causing them to spread out over wide areas unless neutralized by ions.

For example, when using a rotary cathode with an electrically isolated anode, the cathode can operate at values up to 40 kW/m of target length. In such an arrangement 80-85% of the energy discharged through the cathode will be converted into heat in the target material, 1-5% of the energy can be converted into thermal radiation and or transferred into coating energy that is transferred to the substrate and chamber, and the remainder is transferred to the anode via the energy of the electrons leaving the plasma and traveling to the anode. For example, a 500V sputtering process at 40 kW/m of target length would produce 80 amperes of electron current flowing from the cathode to the anode, which at an anode voltage ranging anywhere from 40 to 100 volts above ground potential equates to anywhere from 3.2 to 8 kW of energy per meter of target length arriving at the anode surface. This power needs to be removed from the anodes to prevent them from overheating and melting.

In a standard magnetically confined sputtering process, the visible plasma is located primarily within the magnetic confinement zone adjacent to the target material, separated primarily by the dark space between the plasma and the target material. Electrons are coming off the target material as a function of the secondary electron emission of the target material and the arrival rate of the ions. The current delivered to the plasma is then controlled by the following equation:

$${I}_{plasma} = ( 1 + {γ}_{SEY} )$$

The secondary electron emission, γ_{SEY}, determines the current delivered to the plasma per ion that hits the target surface. Thus, as the secondary electron emission increases for reactive sputtering of most oxides, the voltage delivered to the target from the power supply will drop and the current will increase for a constant power. The increase in the secondary electron emission corresponds with an increase in the heating to the target material and corresponding reduction in the sputter yield. Thus, the sputter rate per input power ratio drops and more energy is lost in the system as heat, as the oxidation level of the material sputtered from the target surface increases. The increased electron current into the plasma has to complete the electrical circuit back to the power supply and thus the electrons exit the magnetic confinement and travel to the anode. If the electron flux density is above a threshold anywhere along the magnetic confinement, spurious plasmas will form outside of the magnetic confinement. These spurious plasmas will act as conductors, allowing a large electron flux to travel through them directly to an anode surface. Plasma is more efficient at delivering electrons to an anode surface due to the space charge neutralization created by the production of ions. These spurious plasmas will divert power away from the sputtering process, lowering the sputtering efficiency; and the excess ion generation can drift back toward the target creating zones of higher sputtering flux which can negatively impact deposition uniformity.

To prevent spurious plasma from forming outside of the primary ExB magnetic confinement zone adjacent to the target surface, the electrons must leave the magnetic confinement with as even of a density along the entire confinement as possible or at least with maximum density anywhere along the confinement under the plasma creation threshold. To accomplish this on sputtering targets with at least one sufficiently long axis, a corresponding anode needs to be provided along the long axis of the target. The proximity of the anode will directly affect the ExB forces on the electrons in the magnetic confinement by changing the electric field at the edge of the plasma confinement. The electric field potential between the anode and the magnetically confined plasma will in turn control the maximum plasma density in the portion of the confinement closest to the anode. The closer the anode, the higher the plasma density in the magnetic confinement due to the larger ExB forces on the electrons within the magnetic confinement, which in turn increases their ionization potential. The electrons escaping the magnetic confinement, primarily through collisions with gas molecules to form ions or metastable species, will want to take the most direct path to the anode along the electric field extending from the edge of the plasma to the anode or the stronger electric field from the exposed target surface outside of the magnetic confinement to the anode. Once outside of the magnetic confinement the electrons are still affected by the magnetic fields produced by the permanent magnets used to create the magnetic confinement, but the magnetic field will no longer be sufficiently strong enough to confine the electrons and the forces from the electric field will dominate the electrons motion along the magnetic field lines toward the anode.

If the magnetic field lines are directed sufficiently toward the anode, then the electron path impedance drops even further allowing the electrons to travel right to the anode with the least amount of work. Anode material selection has traditionally focused on high electrical conductivity to eliminate any resistive losses in the anodes that could cause voltage differentials along the length of sufficiently long anodes and would reduce resistive heating of the anodes. Many anodes are constructed from copper as it provides the highest electrical conductivity with a relatively low oxidation rate at a cost that is a fraction of that of silver, with a marginally lower electrical conductivity than silver. Copper anodes have been implemented in both actively cooled and completely radiantly cooled versions in many large area sputtering applications with good success. Magnetic steel anodes have also been used with relatively good success to reduce the magnetic impedance between the target and the anode surface. The issue with steel or iron anodes is that they have a relatively poor thermal and electrical conductivity compared to copper. Iron is around 6 times less electrically conductive than copper and magnetic stainless steels are more than 10 times less electrically conductive. In addition, magnetic materials will suffer large inductive losses within the material in the frequency range of 40 to 150 kHz that many pulse DC sputtering processes are run at. Copper, however, is non-magnetic and in the presence of static DC, magnetic fields will be essentially invisible. Thus, while copper is advantageous in its electrical conductivity, it is disadvantageous for reducing the magnetic impedance between the target and the anode surface.

Accordingly, there is a need in the art to provide an anode design that would provide high electrical conductivity and reduced resistive heating, while also reducing the magnetic impedance between the target and the anode surface.

### SUMMARY

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

To improve upon the commonly used copper or magnetic stainless steel or iron anodes, embodiments of the current invention add a magnetic core to the center of an actively cooled copper anode to direct the weaker magnetic fields outside of the confinement zone toward the anode, which in turn reduces the magnetic impedance on the electrons. A magnetic core is a piece of magnetic material with a high magnetic permeability used to confine and guide magnetic fields. This reduction in the magnetic impedance coupled with the high electrical conductivity of the copper exterior of the anode produces an anode that can reduce the production of spurious plasmas outside of the primary magnetic confinement by shortening the path between the cathode and anode and reducing the required kinetic energy of electrons required to cross the secondary magnetic field lines to reach the anode. Encapsulating a magnetic core within a water-cooled copper anode has the added benefit of eliminating the inductive heating of the magnetic material in the frequency ranges commonly used for pulse DC sputtering. The copper exterior of the anode carries all the electron current back to the feedthrough, completely bypassing the magnetic core hidden within. The magnetic core in turn helps reduce the magnitude of AC magnetic fields produced around the outside of the copper exterior of the anode; these magnetic fields can increase the electron path impedance between the cathode and anode and cause the electrons to enter the anode only where the magnetic fields are weakest.

Aspects of the disclosure include an anode for a sputtering chamber, comprising: a round pipe made of material having electrical conductivity greater than 1e-7 S/m, and a magnetically permeable core positioned coaxially within the round pipe, the space is included between interior surface of the round pipe and exterior surface of the magnetically permeable core forming a fluid conduit coupled to supply of cooling fluid. The magnetically permeable core is made of material having magnetic permeability greater than 1e-4 H/m. The round pipe may be made of copper, while the magnetically permeable core may be made of magnetic steel or iron.

Aspects of the disclosure also include a sputtering chamber, comprising: a vacuum enclosure; at least one round sputtering target having a magnetron positioned therein and forming a cathode thereby maintaining a plasma within the vacuum enclosure; at least one anode positioned within the vacuum enclosure, completing electrical circuitry of the sputtering chamber, the anode comprising: a round pipe made of material having electrical conductivity greater than 1e-7 S/m; and, a magnetically permeable core positioned coaxially within the round pipe, a space between interior surface of the round pipe and exterior surface of the magnetically permeable core forming a fluid conduit coupled to supply of cooling fluid. The sputtering chamber may further comprise a shield positioned to block the direct line-of-sight from the plasma to the anode, and the shield may be grounded or electrically floating. The shield may be shaped as half pipe having circular, oval or rectangular cross-section. The magnetically permeable core may be made of material having magnetic permeability greater than 1e-4 H/m. The round pipe may be made of copper and the magnetically permeable core may be made of magnetic steel or iron. Also, the sputtering chamber may have two round sputtering target positioned within the vacuum enclosure; and two anodes are positioned between the two round sputtering targets. Further, two elongated shields may be included, each positioned to block line-of-sight from the plasma to a corresponding anode. Each of the elongated shields may be grounded or electrically floating. The magnetically permeable core may be made of material having magnetic permeability greater than 1e-4 H/m. The round pipe may be made of copper and the magnetically permeable core may be made of magnetic steel or iron. Each of the anodes may be oriented parallel to one of the round sputtering targets.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

Other features and advantages of the invention will become apparent from the following description of non-limiting exemplary embodiments, with reference to the appended drawings, in which:

FIG. 1 is a cross-section schematic of a sputtering chamber having an anode according to disclosed embodiment, while FIG. 1A is a top-isometric view illustrating the positioning of the sputtering targets and anodes within the chamber, according to one embodiment.

FIGS. 2A-2C illustrate magnetic field lines, electric field lines, and ExB potentials inside the sputtering chamber utilizing anodes according to disclosed embodiments.

FIG. 3 is a cross-section of another embodiment wherein a single rotating target and a single anode are positioned within the vacuum enclosure.

FIG. 4 illustrates an embodiment having two cylindrical rotating targets and four anodes.

### DETAILED DESCRIPTION

Embodiments of the inventive anode will now be described with reference to the drawings. Different embodiments or their combinations may be used for different applications or to achieve different benefits. Depending on the outcome sought to be achieved, different features disclosed herein may be utilized partially or to their fullest, alone or in combination with other features, balancing advantages with requirements and constraints. Therefore, certain benefits will be highlighted with reference to different embodiments, but are not limited to the disclosed embodiments. That is, the features disclosed herein are not limited to the embodiment within which they are described, but may be “mixed and matched” with other features and incorporated in other embodiments, even if such are not explicitly described herein.

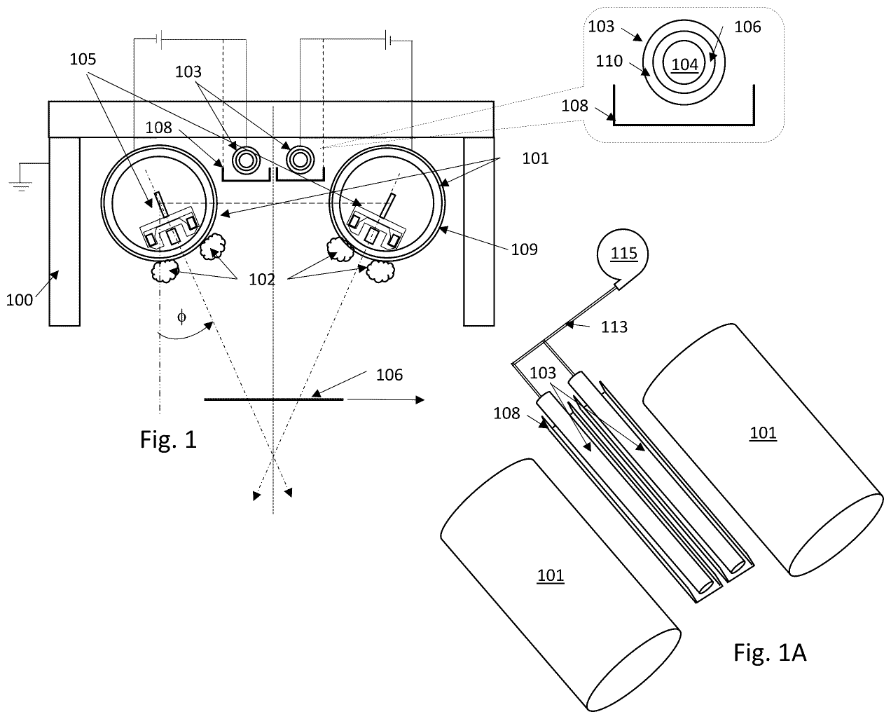

FIG. 1 illustrates a cross-section of an upper part of an embodiment of a sputtering chamber 100 housing two rotating cylindrical targets 101, and includes reference lines that describe spatial orientation and relationship among the various elements of the chamber. The cylindrical targets 101 extend into the page and rotate about rotational axis during the sputtering process. The bottom part that generally contains implements for holding one or more substrates 106 is omitted for clarity, as any arrangement for placing the substrate in the proper position for sputtering may be used in this embodiment. In this particular embodiment, the substrate 106 may be sputtered while stationary at the position shown or while continuously moving in a direction shown by the solid arrow, e.g., by conveyor belt or moving substrate carrier.

Each of the cylindrical targets 101 has a target material layer 109 of a material to be sputtered off the target by ions from the plasma 102, and then deposited onto the substrate 106 as coating. As illustrated, the two magnetrons 105 within the cylindrical targets 101 are tilted towards one another, such that the sputtered material coming off of the target material layer 109 from the ion bombardment lands on the substrate in a controlled distribution that minimizes the sputtered material loss to other surfaces within the vacuum chamber. Generally, the magnetrons 105 may be oriented vertically (e.g., pointing downwards), as shown by the dash-two-dots line, i.e., with its axis of symmetry orthogonal to the floor of the chamber, or be tilted at an angle ϕ from the vertical, as in FIG. 1. Angle ϕ may be +/−0°-60° from the vertical, +/−15°-45° from the vertical, e.g., 30° from the vertical. In other words, each magnetron 105 is positioned with its axis of symmetry crossing the horizontal plane at an orthogonal angle of 90° or with an acute angle of up to 30°.

Each of the magnetrons 105 defines an axis of symmetry that passes through its center, represented in FIG. 1 by the dash-dot arrows. The axes of symmetry of the two magnetrons cross each other at a point ahead of the surfaces of the rotating targets. When the two rotating targets are positioned horizontally, i.e., a straight line passing through their axis of rotation is horizontal line (see wide-dash line), the two axes of symmetry cross each other at a crossing point below the horizontal line. Additionally, a straight vertical line connecting the crossing point and midpoint between the targets is perpendicular to the horizontal line (see dotted line in FIG. 1).

In the embodiment of FIG. 1, two rotating targets 101, electrically isolated from chamber ground, form the cathodes by being connected to the negative terminals of a power supplies are positioned within the sputtering chamber 100, and two corresponding anodes 103, also electrically isolated from chamber ground, are connected to the positive terminals of the same power supplies so as to complete the electrical circuit. FIG. 1A is a general schematic illustrating a top isometrical view of the targets 101 and the cooled anodes 103, to provide an example of the relative orientation of the targets and anodes. A cross-section of one anode 103 is shown in more details in the callout of FIG. 1. Each anode 103 comprises an outer round pipe (a conduit) 110, a magnetic core 104 suspended concentrically within the outer round pipe 110 and fluid cooling channel 106 formed between the outer copper pipe 110 and the magnetic core 104. The outer round pipe 110 is connected to ground, while the magnetic core 104 may be electrically floating, i.e., isolated from the electrical circuitry of the sputtering chamber. The outer round pipe 110 has an exterior surface that is exposed to the plasma and is made of material with an electrical conductivity greater than 1e-7 S/m (siemens per meter), e.g., the outer round pipe may be made out of copper. The magnetic core is made out of material having magnetic permeability greater than 1e-4 H/m (Henries per meter), e.g., made out of magnetic steel or iron. Cooling liquid, e.g., water, is flown through the fluid cooling channel 106 to cool the anode 103. FIG. 1A schematically illustrates piping 113 for circulating coolant from reservoir 115 and the anodes 103. Reservoir 115 may include a chiller or heat exchanger to cool the coolant returned from the anodes 103.

With this arrangement, the magnetic core 104 directs the weaker magnetic fields outside of the confinement zone toward the anode, which reduces the magnetic impedance on the electrons. This reduction in the magnetic impedance coupled with the high electrical conductivity of the outer copper pipe 110 produces an anode that can reduce the production of spurious plasmas outside of the primary magnetic confinement by shortening the path between the cathode and anode and reducing the required kinetic energy of electrons required to cross the secondary magnetic field lines to reach the anode. Encapsulating a magnetic core 104 within fluid cooling channel 106 has the added benefit of eliminating the inductive heating of the magnetic material in the frequency ranges commonly used for pulse DC sputtering. The outer copper pipe 110 carries all the electron current back to the feedthrough, completely bypassing the magnetic core 104 hidden within. The magnetic core 104 in turn helps reduce the magnitude of AC magnetic fields produced around the outside of the outer copper pipe 110; these magnetic fields can increase the electron path impedance between the cathode and anode and cause the electrons to enter the anode only where the magnetic fields are weakest.

Sputtering processes are often used to deposit a coating that is electrically insulative. For example, sputtering may be used to deposit various optical coatings on glass substrates, such as protective glass used in various mobile computing devices. The coatings may include anti-reflective coating, any-scratch coating, etc. These coatings may be made of oxides of silicon, oxides of aluminum, oxides of aluminum silicon alloy, etc., which are electrically insulative materials. During the sputtering process some of the sputtered material ends up on various parts of the processing chamber interior. Since the anode must be exposed to the plasma so as to remove electrons from the plasma, insulative sputtering material may accumulate of the anode, thereby diminishing its effectiveness in providing grounding path to the electrons.

If the anode is directly coated by the sputtering process which is depositing an electrically insulating coating, then the anode will become coated over time until the remaining uncoated anode surface area drops below the threshold required to start a spurious plasma outside of the magnetic confinement. The spurious plasma can then direct all the anode current to a single point on the anode, potentially causing damage to the anode surface due to intense localized heating. The eventual single point nature of an anode that gets coated up will also negatively affect the ExB forces in the magnetic confinement zone responsible for sputtering the targets which will lead to non-uniform sputtering. Therefore the location and arrangement of the anode is also critical to the continual function of the anode throughout a sputtering process lifetime. The anodes should be in a position proximal to the target surface in an arrangement that minimizes the coating of the anode surface.

As illustrated in FIGS. 1 and 1A, a partial shield 108 is provided to block a direct line of sight between the plasma and the anode. The anode is exposed to the interior of chamber from various directions, but not via direct line of sight from the plasma. Consequently, any particle from the plasma must take circuitous route in order to bypass the shield 108 and contact the anode 103. In the embodiment shown in FIGS. 1 and 1A the shield 108 is formed as an elongated half-pipe, which may have any desired cross-section, here it is rectangular cross section, but it may be circular, oval, etc. The shield is grounded or electrically isolated (the dashed line indicating optional grounding) and is positioned between the plasma production and the anode, such that it prevents line of sight coating from forming on the anode surface.

Even with the line-of-sight coating blocked, an anode will still become coated over time due to the negative space charge created by the electron flux leaving the magnetically confined plasma and the presence of ions that will attempt to neutralize that negative space charge by following it all the way to the anode surface. Electrically insulating sputtered species can become ionized and follow the electrons to the anode surface. Depending on the velocity of the ionized species approaching the positively charge anode surface and the voltage of the anode surface, the ions can still contact the anode surface if their incoming velocity exceeds the repelling force of the positive electric field. However, these particles are typically many orders of magnitude heavier than the light electrons and will arrive at the surface from a line-of-sight direction and will be blocked by the shield 108, as the particles will be unable to turn around the surfaces of the shield 108. Regardless of the shape and coverage of the shield 108, when the anode 103 is formed as a round tube, only the part of the surface of the anode that faces away from the shield can become coated with an insulating material, leaving more than 50% of the anode surface area (which faces the shield 108) uncoated even over long periods of time in the deposition system. Thus, the combination of positioning the anode in close proximity to the cathode, making the anode out of a copper pipe, and placing a shield to block line-of-sight from the plasma to the anode, protects the anode from being coated by insulative material and hence elongates the effective service time of the anode.

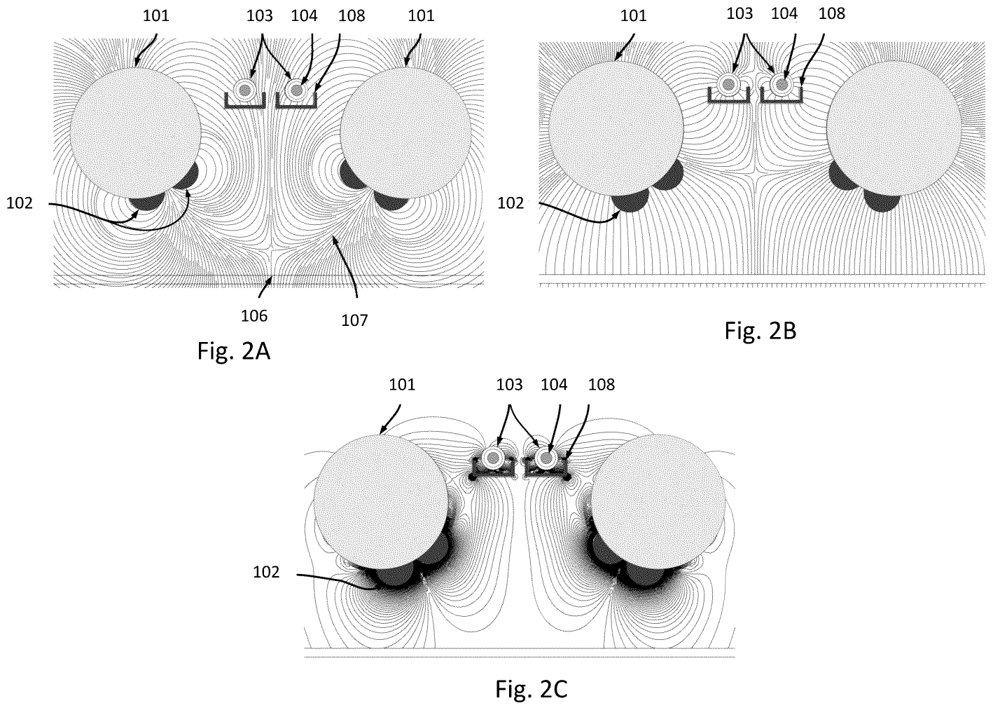

FIG. 2A illustrate field lines indicating the magnetic field 107 inside a sputtering chamber according to one embodiment. The magnetic field lines 107 shown in FIG. 2A are produced by the permanent magnet assembly of the magnetron 105, which is located withing the sputtering targets 101. In the illustrated example, the sputtering targets 101 sputters at an angle of incidence of 30 degrees onto a substrate 106. Two water cooled anode tubes 103 are positioned symmetrically between the two targets 101. FIG. 2B illustrates the electric field lines, while FIG. 2B illustrated the ExB potentials, which indicate the plasma production impedance.

With the disclosed embodiments, the anodes include magnetic cores embedded within electrically conductive conduit. Electrons follow the magnetic field lines from the cathodes to the anodes. If the anodes are just copper as in the prior art, which is ideal for the electrical conductivity, then magnetic fields build up around the anodes as a function of the electron current flowing into the anodes. Adding a magnetic core within the copper anodes allows the strong permanent magnets to couple with the magnetic steel core in each anode and the electrons can be distributed more effectively to the entire anode surface, as evident from FIGS. 2A-2C. Without the magnetic cores the magnetic field generated around the anodes from the electron current flowing through the anode will push the electron to the end of the anode which causes plasma uniformity problems. Conversely, using mild steel anodes to help reduce plasma uniformity is not as good of an electrical conductor as copper and is prone to overheating due to induced eddy currents from the pulse frequency of the power causing indicative heating. The copper tube anodes with a magnetic steel core of the current invention have the added benefits of the magnetic field shaping that the mild steel anodes utilized with the added benefit of the high electrical conductivity of copper anodes. Also, by leaving space between the magnetic core and the copper conduit, coolant can be flown within the space to control the temperature of the anode.

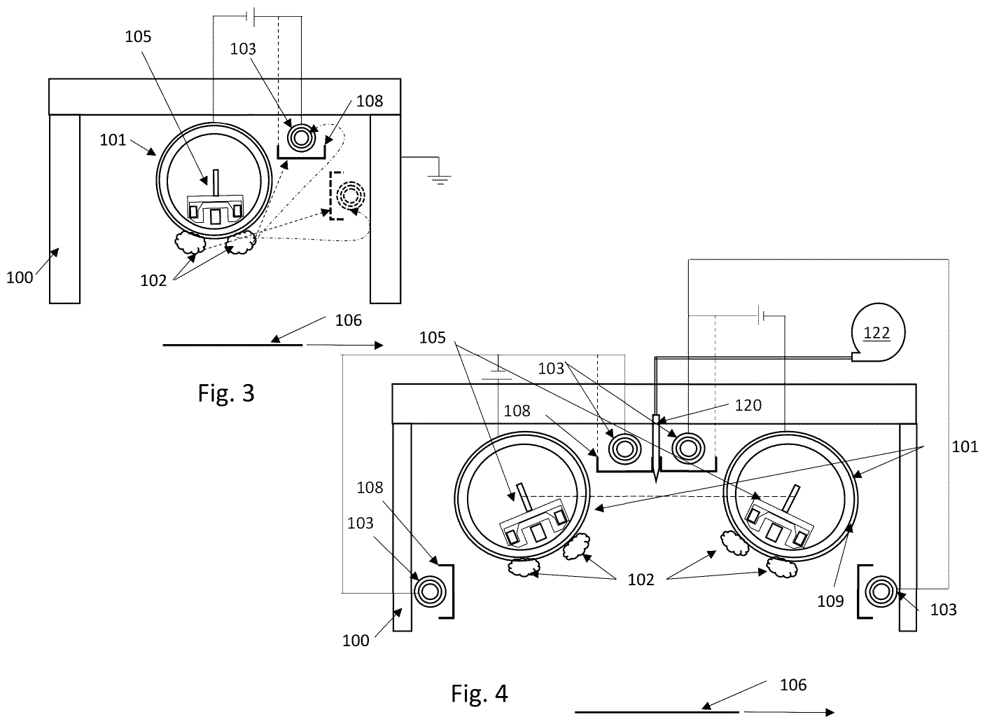

FIG. 3 illustrates an embodiment of a sputtering chamber having a single target 101 and a single anode 103 within the vacuum enclosure. In this embodiment the magnetron is oriented vertically, such that its axis of symmetry passes perpendicularly to the substrate. The plasma is then ignited in the space between the substrate and the target. One liquid cooled anode 103 with corresponding shield 108 is provided next to the target 101, either towards the ceiling or next to one of the sidewalls, as shown in dotted lines. In either case, the shield 108 is configured to prevent line of sight approach from the plasma to the anode, as shown by the dashed-line arrows. Rather, a particles approaching from the plasma must take a circuitous route in order to by-pass the shield 108 and reach the anode 103, as shown by the dash-dot curved arrows. By line-of-sight it is meant that a straight line from anywhere within the plasma must intersect the shield before it can connect with the anode. Thus, a particle emanating from the plasma cannot reach the anode by straight-line flight, but rather must execute a curved flight path. Consequently, heavier ions that cannot execute the required curved flight path cannot reach the anode, while lighter electrons can reach the anode.

FIG. 4 illustrates yet another embodiment, wherein two cylindrical rotating targets 101 are positioned within the vacuum chamber. In this embodiment, two anodes 103 are symmetrically positioned on the ceiling of the vacuum chamber, and two anodes 103 are symmetrically positioned, one on each sidewall of the vacuum chamber. Each anode 103 has a corresponding shield 108 positioned to block line-of-sight approach from anywhere within the confined plasma 102. Also, gas injector 120 is positioned on the ceiling and is centrally located between the anodes 103 and centrally located between the targets 101. Thus, gas from gas source 122 is injected between the two targets from a space between the two anodes 103.

While this invention has been discussed in terms of exemplary embodiments of specific materials, and specific steps, it should be understood by those skilled in the art that variations of these specific examples may be made and/or used and that such structures and methods will follow from the understanding imparted by the practices described and illustrated as well as the discussions of operations as to facilitate modifications that may be made without departing from the scope of the invention defined by the appended claims.

1. A anode for a sputtering chamber, comprising:
an elongated conduit having an external surface exposed to interior space of the sputtering chamber and made of material having electrical conductivity greater than 1e-7 S/m; and,
a magnetically permeable core positioned coaxially within the elongated conduit, a space between interior surface of the elongated conduit and exterior surface of the magnetically permeable core forming a fluid conduit coupled to supply of cooling fluid.

2. The anode of claim 1, wherein the magnetically permeable core is made of material having magnetic permeability greater than 1e-4 H/m.

3. The anode of claim 1, wherein the elongated conduit is made of copper.

4. The anode of claim 1, wherein the magnetically permeable core is made of magnetic steel or iron.

5. A sputtering chamber, comprising:
a vacuum enclosure;
at least one magnetically confined sputtering target positioned within the vacuum enclosure;
at least one anode positioned within the vacuum enclosure, completing electrical circuit of a sputtering process performed within the vacuum enclosure, the anode comprising:
a pipe made of material having electrical conductivity greater than 1e-7 S/m; and,
a magnetically permeable core positioned coaxially within the pipe, a space between interior surface of the pipe and exterior surface of the magnetically permeable core forming a fluid conduit coupled to supply of cooling fluid.

6. The sputtering chamber of claim 5, further comprising a shield positioned to block line-of-sight from the plasma to the anode.

7. The sputtering chamber of claim 5, wherein the shield is grounded.

8. The sputtering chamber of claim 5, wherein the shield is electrically floating.

9. The sputtering chamber of claim 5, wherein the shield is shaped as half pipe having circular, oval or rectangular cross-section.

10. The sputtering chamber of claim 5, wherein the magnetically permeable core is made of material having magnetic permeability greater than 1e-4 H/m.

11. The sputtering chamber of claim 5, wherein the pipe is made of copper.

12. The sputtering chamber of claim 5, wherein the magnetically permeable core is made of magnetic steel or iron.

13. The sputtering chamber of claim 5, wherein:
two round sputtering targets are positioned within the vacuum enclosure; and
two anodes are positioned between the two round sputtering targets.

14. The sputtering chamber of claim 13, further comprising two elongated shields, each positioned to block line-of-sight from the plasma to a corresponding anode.

15. The sputtering chamber of claim 14, wherein each of the elongated shields is grounded.

16. The sputtering chamber of claim 14, wherein each of the elongated shields is electrically floating.

17. The sputtering chamber of claim 14, wherein the magnetically permeable core is made of material having magnetic permeability greater than 1e-4 H/m.

18. The sputtering chamber of claim 14, wherein the pipe is made of copper.

19. The sputtering chamber of claim 14, wherein the magnetically permeable core is made of magnetic steel or iron.

20. The sputtering chamber of claim 14, wherein each of the anodes is oriented parallel to one of the round sputtering targets.
